(19) United States
(12) Patent Application Publication
(10) Pub. No.: US 2006/0113533 A1
(43) Pub. Date: Jun. 1, 2006

(54) Semiconductor device and layout design method for the same

(76) Inventors: Yasuhiro Tamaki, Kyoto (JP); Kyoji Yamashita, Kyoto (JP); Katsuhiro Otani, Nara (JP)

Correspondence Address: MCDERMOTT WILL & EMERY LLP, 600 13TH STREET, N.W., WASHINGTON, DC, 20005-3096, US

(21) Appl. No.: 11/202,210

(22) Filed: Aug. 12, 2005

(30) Foreign Application Priority Data
Nov. 30, 2004 (JP) 2004-346356

(51) Int. Cl. H01L 23/58

(52) U.S. Cl. 257/48

(57) ABSTRACT

In layout design of a semiconductor device including a device forming region formed on a substrate; an isolation region formed on the semiconductor substrate so as to surround the device forming region; a gate electrode formed on the device forming region; and a gate interconnect connected to the gate electrode and formed on both sides of the device forming region on the isolation region, the semiconductor device is designed as follows: The gate interconnect has a first portion with a larger dimension along the gate length direction than the gate electrode on one side of the device forming region and has a second portion with a larger dimension along the gate length direction than the gate electrode on the other side of the device forming region; and a distance between the first portion and the device forming region is equal to a distance between the second portion and the device forming region.

### CROSS-REFERENCE TO RELATED APPLICATIONS

This application claims priority under 35 U.S.C. §119 on Patent Application No. 2004-346356 filed in Japan on Nov. 30, 2004, the entire contents of which are hereby incorporated by reference.

### BACKGROUND OF THE INVENTION

The present invention relates to a semiconductor device including a refined transistor, and more particularly, it relates to countermeasure against dimensional variation caused by a mask alignment shift or an optical proximity effect in fabrication process for semiconductor devices.

Principal factors for causing variation in propagation delay time in design of a semiconductor integrated circuit (LSI) are an operation power voltage, a temperature, process variation and the like. Also, in LSI design, the operation of an LSI should be guaranteed even when all the conditions are the worst. A gate length and a gate width of a transistor are significant elements for defining the operation of the transistor, and influence of variations in the gate length or the gate width occupies a very large proportion in the process variation. Furthermore, in accordance with development in refinement of transistors, the gate length and the gate width are reduced and hence their variation is increased. Therefore, since variation in the propagation delay time is increased and hence a design margin is increased, it has become difficult to provide LSIs with high performance.

In general, in the semiconductor fabrication process, photolithography process including resist application, exposure and development, etching process for patterning an element by using a resist mask and resist removing process are repeatedly carried out, so as to form an integrated circuit on a semiconductor substrate. Also in forming a gate of a transistor, the photolithography process, the etching process and the resist removing process are performed. In the exposure of the photolithography process, when the dimension of a pattern is smaller than the wavelength of exposing light, an error between a layout dimension set in the design and an actual pattern dimension formed on a semiconductor substrate is increased due to an optical proximity effect caused by influence of diffracted light.

Examples of the technique for overcoming this problem are super-resolution technique using a phase shift mask and OPC (optical proximity correction) technique for correcting the influence of the optical proximity effect by correcting a circuit pattern drawn on a mask.

### SUMMARY OF THE INVENTION

The optical proximity effect is, however, unavoidable in principle, and therefore, it is difficult to avoid the optical proximity effect merely by the fabrication/process technique such as the super-resolution technique and the OPC technique, and there is a demand for an optical proximity effect-friendly structure of a semiconductor device from the design side.

Specifically, an object of the invention is providing a structure of a semiconductor device and a layout design method in which a high performance LSI can be realized even through refinement process by suppressing the variation in a gate length or a gate width mainly caused by the optical proximity effect.

The present inventors have examined the cause of the variation in the gate length, resulting in finding the following: Since the diameter of a gate contact is larger than the gate length, it is necessary to design a portion of a gate interconnect corresponding to the gate contact to be larger than a gate electrode. This is one cause of the variation in the gate length.

FIGS. 12A through 12D are diagrams for showing an example of the variation in the gate length caused because a gate contact portion of a gate interconnect is larger than a gate electrode.

FIG. 12A is a diagram of an exemplified layout of a semiconductor device having a transistor structure. As shown in FIG. 12A, a P-type impurity diffusion region 11 and an N-type impurity diffusion region 12 each surrounded with an isolation region (not shown) are formed to be adjacent to each other on a semiconductor substrate (not shown). On the P-type impurity diffusion region 11 and the N-type impurity diffusion region 12, a conductive pattern corresponding to a gate electrode 13 and a gate electrode 14 is formed, and the conductive pattern extends over the isolation regions on the both sides of the impurity diffusion regions 11 and 12 so as to form a gate interconnect 15. In other words, the gate electrode 13 and the gate electrode 14 are electrically connected to each other through the gate interconnect 15. Source/drain contacts 16 are disposed on both sides of the gate electrode 13 on the P-type impurity diffusion region 11, and source/drain contacts 17 are disposed on both sides of the gate electrode 14 on the N-type impurity diffusion region 12. The gate interconnect 15 has, between the P-type impurity diffusion region 11 and the N-type impurity diffusion region 12, a contact portion 15a having a larger dimension along the gate length direction than the gate electrodes 13 and 14, and a gate contact 18 is provided on the contact portion 15a.

In the case where the semiconductor device having the layout of FIG. 12A is fabricated through the semiconductor device fabrication process including the photolithography process, the etching process and the resist removing process, gate flaring derived from the optical proximity effect occurs as shown in FIG. 12B because of the width change of the gate interconnect 15 between the contact portion 15a and the other portion. When this gate flaring reaches the gate electrode formed on the impurity diffusion region, the gate length is increased at the edge of the impurity diffusion region, resulting in changing the electric characteristic. Specifically, as shown in FIG. 12B, the gate flaring having occurred in the gate interconnect 15 in the vicinity of the contact portion 15a reaches portions of the gate electrode 13 and the gate electrode 14 close to the contact portion 15a in the P-type impurity diffusion region 11 and the N-type impurity diffusion region 12.

FIG. 12C shows a state where an alignment shift between GA (gate electrode)/OD (impurity diffusion region) photomasks occurs in the case where the semiconductor device having the layout of FIG. 12A is fabricated through the semiconductor device fabrication process including the photolithography process, the etching process and the resist removing process. In this case, the gate length is largely varied as shown in FIG. 12C. Specifically, the gate length of the gate electrode 14 provided on the N-type impurity diffusion region 12 is largely varied as shown in FIG. 12C.

FIG. 12D shows a state where an alignment shift between GA/OD photomasks occurs in the case where a semiconductor device having a layout obtained by rotating the layout of FIG. 12A by 180° is fabricated through the semiconductor device fabrication process including the photolithography process, the etching process and the resist removing process. Also in this case, the gate length is largely varied as shown in FIG. 12D. Specifically, the gate length of the gate electrode 13 provided on the P-type impurity diffusion region 11 is largely varied as shown in FIG. 12D. Also, it is understood from FIGS. 12C and 12D that the gate length on each impurity diffusion region is largely varied between a transistor arrangement direction (corresponding to the direction of current flow through a channel of the transistor; for example, when the direction shown in FIG. 12C is regarded as a reference (0°), the direction shown in FIG. 12D is 180°) of 0° and a transistor arrangement direction of 180°. In other words, it is obvious that the electric characteristic of a transistor is largely varied depending upon the transistor arrangement direction.

Furthermore, as shown in FIGS. 12C and 12D, in the case where the alignment shift between the GA/OD photomasks and the gate flaring both occur, not only the gate length of the transistor but also the effective gate width is varied, and the degree of the variation depends upon the transistor arrangement direction.

When the electric characteristic of the transistor is thus varied depending upon the transistor arrangement direction, the process variation is increased and clock skew or the like of the LSI is increased. Therefore, even when the circuit is refined, it is difficult to improve the performance of the LSI chip.

On the basis of the aforementioned findings, the present inventors have attained the invention in which gate contact portions of a gate interconnect formed on both sides of an impurity diffusion region, namely, a device forming region, are laid out to be symmetrical with respect to the isolation region.

Specifically, according to the present invention, portions of a gate interconnect having a larger dimension along the gate length direction than a gate electrode are laid out to be symmetrical with respect to a device forming region. Therefore, even when the gate flaring or the alignment shift between the GA/OD photomasks occurs, transistors whose arrangement directions are different from each other by 180° can be the same in the shape of their gate electrodes. Accordingly, variation in the gate length and the gate width derived from the optical proximity effect or the like can be suppressed, so as to suppress variation in the electric characteristic between transistors. As a result, a high performance LSI can be realized through refinement process.

Also, the present invention is applicable to LSIs built on a variety of electric equipment and more particularly, a high performance LSI with small variation in a gate length and a gate width among MIS (metal insulator semiconductor) transistors.

### BRIEF DESCRIPTION OF THE DRAWINGS

FIG. 1A is a plan view of a design shape of a semiconductor device according to Embodiment 1 of the invention and FIGS. 1B, 1C and 1D are plan views of fabricated shapes of the semiconductor device of Embodiment 1;

FIG. 2A is a plan view of a design shape of a semiconductor device according to Modification 1 of Embodiment 1 of the invention and FIG. 2B is a plan view of a fabricated shape of the semiconductor device of Modification 1 of Embodiment 1;

FIG. 3A is a plan view of a design shape of a semiconductor device according to Modification 2 of Embodiment 1 of the invention and FIG. 3B is a plan view of a fabricated shape of the semiconductor device of Modification 2 of Embodiment 1;

FIG. 4A is a plan view of a design shape of a semiconductor device according to Modification 3 of Embodiment 1 of the invention and FIG. 4B is a plan view of a fabricated shape of the semiconductor device of Modification 3 of Embodiment 1;

FIG. 5A is a plan view of a design shape (a shape of a gate polysilicon film) of a semiconductor device according to Embodiment 2 of the invention, FIG. 5B is a plan view of a shape of an insulating sidewall formed on the side face of a gate electrode additionally shown in FIG. 5A and FIG. 5C is a plan view of an alignment shift between GA/OD photomasks additionally shown in FIG. 5B;

FIG. 6 is a plan view of a shape of a pattern actually formed on a semiconductor substrate when the semiconductor device having the design shape of FIG. 5A is fabricated through given semiconductor device fabrication process;

FIG. 7 is a plan view of a shape of a pattern actually formed on a semiconductor substrate when the semiconductor device having the design shape of FIG. 5A is fabricated through the given semiconductor device fabrication process;

FIG. 8 is a plan view of a design shape of a semiconductor device according to Modification 3 of Embodiment 2;

FIG. 9A is a plan view of design shapes of a first CMOS transistor pair and a second CMOS transistor pair included in a semiconductor device according to Embodiment 3 and FIG. 9B is a plan view of an exemplified design shape of a logic circuit including the first CMOS transistor pair and the second CMOS transistor pair of FIG. 9A connected in parallel;

FIG. 10A is a plan view of a design shape of a CMOS transistor pair included in a semiconductor device according to a comparative example and FIG. 10B is a plan view of an exemplified design shape of a logic circuit including the CMOS transistor pair of FIG. 10A;

FIG. 11 is a schematic diagram of a clock tree of an LSI according to Embodiment 4 of the invention; and

FIGS. 12A, 12B, 12C and 12D are diagrams for showing examples of variation in a gate length caused because a gate contact portion is wider than a gate electrode in a conventional technique.

### DETAILED DESCRIPTION OF THE INVENTION

### Embodiment 1

Now, a semiconductor device according to Embodiment 1 and a layout design method for the same will be described with reference to the accompanying drawings.

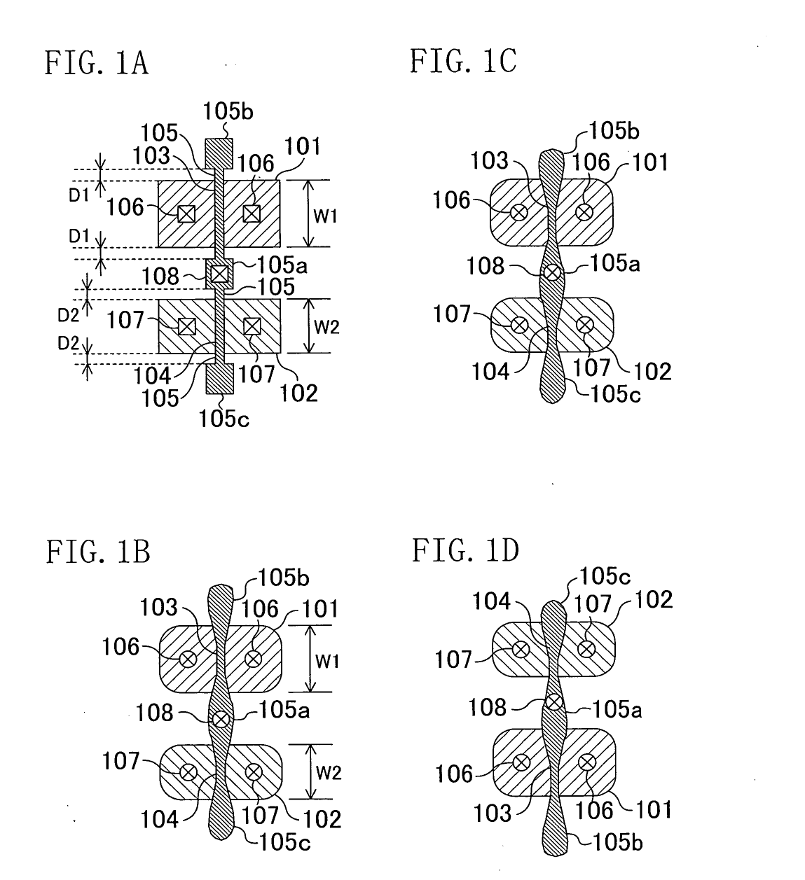

FIG. 1A is a plan view of a design shape of the semiconductor device of Embodiment 1 and FIGS. 1B through 1D are plan views of fabricated shapes of the semiconductor device of Embodiment 1.

As shown in FIG. 1A, a P-type impurity diffusion region 101 and an N-type impurity diffusion region 102 each surrounded with an isolation region (not shown) of STI (shallow trench isolation) or the like are formed on a semiconductor substrate (not shown) to be adjacent to each other. A conductive pattern (of, for example, a gate polysilicon film) corresponding to a gate electrode 103 and a gate electrode 104 is formed on the P-type impurity diffusion region 101 and the N-type impurity diffusion region 102, and the conductive pattern extends over the isolation region disposed on the both sides of the impurity diffusion regions 101 and 102 so as to form a gate interconnect 105. At this point, the gate electrode 103 and the P-type impurity diffusion region 101 together form a P-type transistor with a gate width W1 and a gate length L, and the gate electrode 104 and the N-type impurity diffusion region 102 together form an N-type transistor with a gate width W2 and a gate length L. Also, the gate electrode 103 and the gate electrode 104 are electrically connected to each other through the gate interconnect 105.

Furthermore, as shown in FIG. 1A, source/drain contacts 106 are disposed on both sides of the gate electrode 103 on the P-type impurity diffusion region 101, and source/drain contacts 107 are disposed on both sides of the gate electrode 104 on the N-type impurity diffusion region 102. The gate interconnect 105 has, between the P-type impurity diffusion region 101 and the N-type impurity diffusion region 102, a contact portion 105a with a larger dimension along the gate length direction than the gate electrodes 103 and 104, and a gate contact 108 to be connected to an upper interconnect is provided on the contact portion 105a.

In this case, as shown in FIG. 1A, as a characteristic of the design shape of the semiconductor device of this embodiment, the gate interconnect 105 has a dummy contact portion 105b in a symmetrical shape to the contact portion 105a with respect to the P-type impurity diffusion region 101 and has a dummy contact portion 105c in a symmetrical shape to the contact portion 105a with respect to the N-type impurity diffusion region 102. In other words, the portions of the gate interconnect 105 having a larger dimension along the gate length direction than the gate electrodes 103 and 104 are designed to be in an identical shape on the isolation region on the both sides of the impurity diffusion regions 101 and 102. Also, a distance between the contact portion 105a and the P-type impurity diffusion region 101 and a distance between the dummy contact portion 105b and the P-type impurity diffusion region 101 are both a distance D1, namely, equal to each other, and a distance between the contact portion 105a and the N-type impurity diffusion region 102 and a distance between the dummy contact portion 105c and the N-type impurity diffusion region 102 are both a distance D2, namely, equal to each other.

FIG. 1B is a plan view of a shape of a pattern actually formed on the semiconductor substrate when the semiconductor device with the design shape of FIG. 1A is fabricated through semiconductor device fabrication process including photolithography process, etching process and resist removing process.

As shown in FIG. 1B, the pattern shape of the gate polysilicon film formed on the semiconductor substrate is largely different from the design shape. Specifically, the dimension along the gate length direction of the gate electrode 103 or 104 formed on the impurity diffusion region 101 or 102 is not uniform along the gate width direction but is increased toward the edge of the impurity diffusion region 101 or 102. It is noted that, also in the fabricated shape shown in FIG. 1B, the contact portion 105a and the dummy contact portion 105b are in a symmetrical shape with respect to the P-type impurity diffusion region 101 and that the contact portion 105a and the dummy contact portion 105c are in a symmetrical shape with respect to the N-type impurity diffusion region 102.

FIG. 1C is a plan view of a shape of a pattern actually formed on the semiconductor substrate in the case where the semiconductor device having the design shape of FIG. 1A is fabricated through the semiconductor device fabrication process including the photolithography process, the etching process and the resist removing process with the etching process and the resist removing process performed after a photomask alignment shift is caused in the photolithography process.

FIG. 1D is a plan view of a shape of a pattern actually formed on the semiconductor substrate in the case where a semiconductor device having a design shape obtained by rotating the design shape of FIG. 1A by 180° is fabricated through the semiconductor device fabrication process including the photolithography process, the etching process and the resist removing process with the etching process and the resist removing process performed after a photomask alignment shift is caused in the photolithography process.

As shown in FIGS. 1C and 1D, even when the photomask alignment shift is caused in the photolithography process, the shapes of the gate electrodes 103 and 104 respectively provided on the impurity diffusion regions 101 and 102 are the same between a transistor arrangement direction of FIG 1C (namely, a direction of 0°) and a transistor arrangement direction of FIG 1D (namely, a direction of 180°).

In this embodiment, the portions of the gate interconnect 105 with the larger dimension along the gate length direction than the gate electrodes 103 and 104 are laid out symmetrically with respect to the impurity diffusion regions 101 and 102. Therefore, even when gate flaring or a GA/OD photomask alignment shift is caused, the shapes of the gate electrodes 103 and 104 respectively provided on the impurity diffusion regions 101 and 102 can be identical even between, for example, transistors whose arrangement directions are different by 180°. Accordingly, also in the case where the GA/OD photomask alignment shift is caused, variation in the electric characteristic between the transistors can be prevented regardless of the transistor arrangement directions.

It is noted that the aforementioned effect can be attained not only when the transistor arrangement directions are different by 180° but also when they are different by 90° or 270°.

In this embodiment, the contact portion 105a and the dummy contact portion 105b are in the symmetrical shape with respect to the P-type impurity diffusion region 101 and the contact portion 105a and the dummy contact portion 105c are in the symmetrical shape with respect to the N-type impurity diffusion region 102. Instead, the same effect can be attained when the contact portion 105a and the dummy contact portion 105b have an identical length in their portions opposing the P-type impurity diffusion region 101 and the contact portion 105a and the dummy contact portion 105c have an identical length in their portions opposing the N-type impurity diffusion region 102.

### Modification 1 of Embodiment 1

Now, a semiconductor device according to Modification 1 of Embodiment 1 and a layout design method for the same will be described with reference to the accompanying drawings.

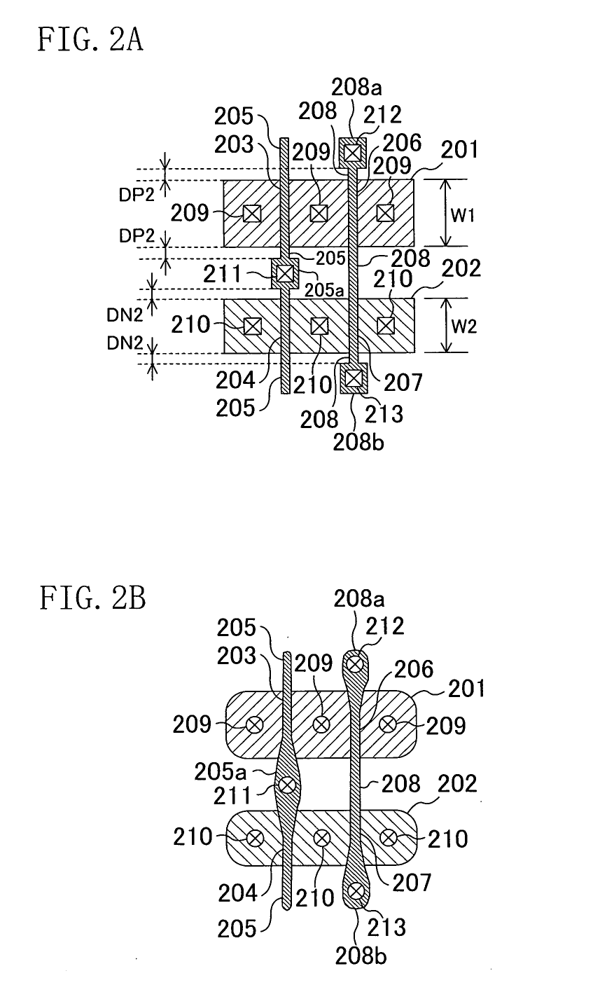

FIG. 2A is a plan view of a design shape of the semiconductor device of Modification I of Embodiment 1 and FIG. 2B is a plan view of a fabricated shape of the semiconductor device of Modification 1 of Embodiment 1.

As shown in FIG. 2A, a P-type impurity diffusion region 201 and an N-type impurity diffusion region 202 each surrounded with an isolation region (not shown) of STI or the like are formed on a semiconductor substrate (not shown) to be adjacent to each other. A first conductive pattern (of, for example, a gate polysilicon film) corresponding to a gate electrode 203 and a gate electrode 204 and a second conductive pattern (of, for example, a gate polysilicon film) corresponding to a gate electrode 206 and a gate electrode 207 are formed on the P-type impurity diffusion region 201 and the N-type impurity diffusion region 202, and the first and second conductive patterns extend over the isolation region disposed on the both sides of the impurity diffusion regions 201 and 202 so as to form a gate interconnect 205 and a gate interconnect 208. In other words, the gate electrode 203 and the gate electrode 204 are electrically connected to each other through the gate interconnect 205 and the gate electrode 206 and the gate electrode 207 are electrically connected to each other through the gate interconnect 208. A plurality of source/drain contacts 209 are disposed on both sides of the gate electrodes 203 and 206 on the P-type impurity diffusion region 201, and a plurality of source/drain contacts 210 are disposed on both sides of the gate electrodes 204 and 207 on the N-type impurity diffusion region 202.

In the semiconductor device of this modification, one transistor includes two adjacent gate electrodes having the same gate length and the same gate width on each of the impurity diffusion regions 201 and 202. Accordingly, in the case where four or a larger even number of gate electrodes are provided on the impurity diffusion regions 201 and 202, transistors are arranged in parallel.

Also, as shown in FIG. 2A, the gate interconnect 205 has, between the P-type impurity diffusion region 201 and the N-type impurity diffusion region 202, a contact portion 205a with a larger dimension along the gate length direction than the gate electrodes 203 and 204, and a gate contact 211 to be connected to an upper interconnect is provided on the contact portion 205a. The dimensions along the gate length direction of portions of the gate interconnect 205 formed respectively on the side of the P-type impurity diffusion region 201 opposite to the N-type impurity diffusion 202 and on the side of the N-type impurity diffusion region 202 opposite to the P-type impurity diffusion region 201 are the same as the dimensions of the gate electrodes 203 and 204.

Also, as shown in FIG. 2A, the gate interconnect 208 has a contact portion 208a with a larger dimension along the gate length direction than the gate electrodes 206 and 207 on the side of the P-type impurity diffusion region 201 opposite to the N-type impurity diffusion region 202 and has a contact portion 208b with a larger dimension along the gate length direction than the gate electrodes 206 and 207 on the side of the N-type impurity diffusion region 202 opposite to the P-type impurity diffusion region 201. Also, gate contacts 212 and 213 to be connected to upper interconnects are provided respectively on the contact portions 208a and 208b. The dimension along the gate length direction of a portion of the gate interconnect 208 formed between the P-type impurity diffusion region 201 and the N-type impurity diffusion region 202 is the same as the dimension of the gate electrodes 206 and 207.

As a characteristic of the design shape of the semiconductor device of this modification, as shown in FIG. 2A, a distance between the contact portion 205a and the P-type impurity diffusion region 201 and a distance between the contact portion 208a and the P-type impurity diffusion region 201 are both a distance DP2, namely, equal to be each other, and a distance between the contact portion 205a and the N-type impurity diffusion region 202 and a distance between the contact portion 208b and the N-type impurity diffusion region 202 are both a distance DN2, namely, equal to each other.

FIG. 2B is a plan view of a shape of a pattern actually formed on the semiconductor substrate when the semiconductor device having the design shape of FIG. 2A is fabricated through the semiconductor device fabrication process including the photolithography process, the etching process and the resist removing process.

As shown in FIG. 2B, the gate electrode 203 and the gate electrode 206 provided on the P-type impurity diffusion region 201 are different in the arrangement direction by 180° but are respectively the same in the shape as the gate electrode 204 and the gate electrode 207 provided on the N-type impurity diffusion region 202.

Also in this modification, although not shown in the drawing, even when a GA/OD photomask alignment shift is caused, there arises no difference in the characteristic among transistors because the gate electrode 203 and the gate electrode 206 provided on the P-type impurity diffusion region 201 are the same in the shape as the gate electrode 206 or the gate electrode 207 provided on the N-type impurity diffusion region 202 when the arrangement direction is rotated by 180°. Furthermore, this effect can be attained also in transistors whose arrangement directions are different by 180° from those of the design shape of FIG. 2A.

In this manner, according to this modification, even when a GA/OD photomask alignment shift is caused, the variation in the electric characteristic among transistors can be prevented regardless of the transistor arrangement directions in the same manner as in Embodiment 1.

It is noted that the aforementioned effect can be attained not only in transistors whose arrangement directions are different by 180° from those of the design shape of FIG. 2A but also in transistors whose arrangement directions are different by 90° or 270° from those of the design shape of FIG. 2A.

Although the two gate interconnects are provided on both sides of the impurity diffusion region, namely, on both sides of the device forming region on the isolation region, in this modification, four or a larger even number of gate interconnects may be provided on the isolation region. In this case, the gate interconnects are designed as follows: Each of a half of gate interconnects out of the even number of gate interconnects has a first portion with a larger dimension along the gate length direction than a gate electrode on a first side of the device forming region and has a dimension along the gate length direction equal to that of the gate electrode on a second side of the device forming region. Furthermore, each of the other half of gate interconnects out of the even number of gate interconnects has a second portion with a larger dimension along the gate length direction than the gate electrode on the second side of the device forming region and has a dimension along the gate length direction equal to that of the gate electrode on the first side of the isolation region. Moreover, a distance between the first portion of each of the half of gate interconnects and the device forming region and a distance between the second portion of each of the other half of gate interconnects and the device forming region are equal to each other.

Modification 2 of Embodiment 1

Now, a semiconductor device according to Modification 2 of Embodiment 1 and a layout design method for the same will be described with reference to the accompanying drawings.

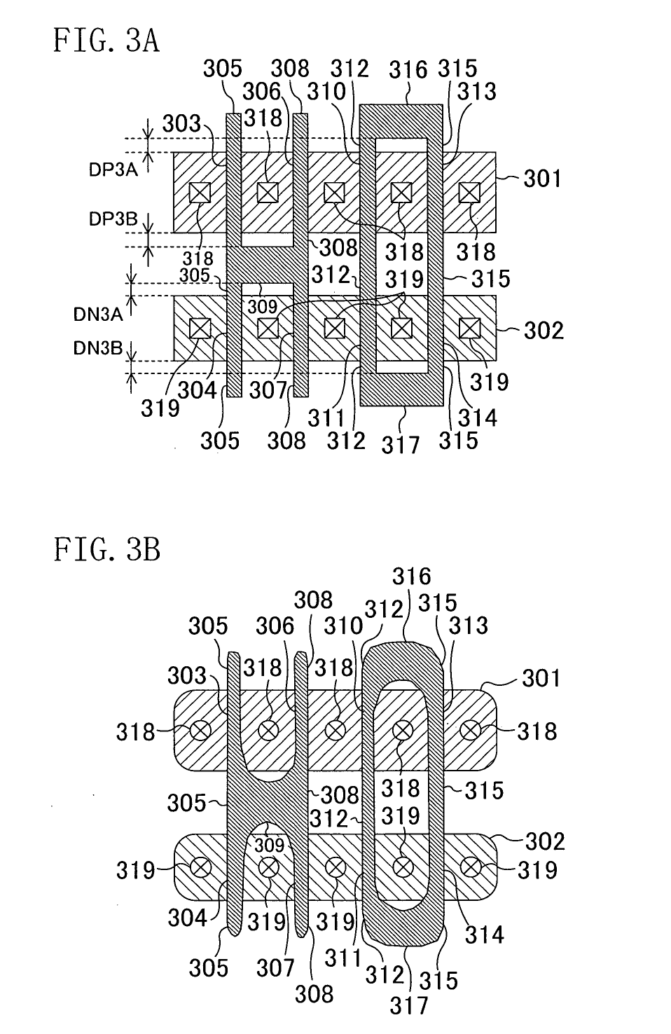

FIG. 3A is a plan view of a design shape of the semiconductor device of Modification 2 of Embodiment 1 and FIG. 3B is a plan view of a fabricated shape of the semiconductor device of Modification 2 of Embodiment 1.

As shown in FIG. 3A, a P-type impurity diffusion region 301 and an N-type impurity diffusion region 302 each surrounded with an isolation region (not shown) of STI or the like are formed on a semiconductor substrate (not shown) to be adjacent to each other.

A first conductive pattern (of, for example, a gate polysilicon film) corresponding to a gate electrode 303 and a gate electrode 304 and a second conductive pattern (of, for example, a gate polysilicon film) corresponding to a gate electrode 306 and a gate electrode 307 are formed to be adjacent to each other on the P-type impurity diffusion region 301 and the N-type impurity diffusion region 302. Also, the first and second conductive patterns extend over the isolation region disposed on the both sides of the impurity diffusion regions 301 and 302 so as to form a gate interconnect 305 and a gate interconnect 308. In other words, the gate electrode 303 and the gate electrode 304 are electrically connected to each other through the gate interconnect 305 and the gate electrode 306 and the gate electrode 307 are electrically connected to each other through the gate interconnect 308. Furthermore, the gate interconnect 305 and the gate interconnect 308 adjacent to each other are connected to each other through a first bridge portion 309 between the P-type impurity diffusion region 301 and the N-type impurity diffusion region 302. The dimensions of portions of the gate interconnect 305 provided respectively on the side of the P-type impurity diffusion region 301 opposite to the N-type impurity diffusion region 302 and on the side of the N-type impurity diffusion region 302 opposite to the P-type impurity diffusion region 301 are the same as the dimension of the gate electrodes 303 and 304, and the dimensions of portions of the gate interconnect 308 provided respectively on the side of the P-type impurity diffusion region 301 opposite to the N-type impurity diffusion region 302 and on the side of the N-type impurity diffusion region 302 opposite to the P-type impurity diffusion region 301 are the same as the dimension of the gate electrodes 306 and 307.

Furthermore, a third conductive pattern (of, for example, a gate polysilicon film) corresponding to a gate electrode 310 and a gate electrode 311 and a fourth conductive pattern (of, for example, a gate polysilicon film) corresponding to a gate electrode 313 and a gate electrode 314 are formed so as to be adjacent to each other on the P-type impurity diffusion region 301 and the N-type impurity diffusion region 302. Also, the third and fourth conductive patterns extend over the isolation region disposed on the both sides of the impurity diffusion regions 301 and 302 so as to form a gate interconnect 312 and a gate interconnect 315. In other words, the gate electrode 310 and the gate electrode 311 are electrically connected to each other through the gate interconnect 312 and the gate electrode 313 and the gate electrode 314 are electrically connected to each other through the gate interconnect 315. Furthermore, the gate interconnect 312 and the gate interconnect 315 adjacent to each other are connected to each other through a second bridge portion 316 on the side of the P-type impurity diffusion region 301 opposite to the N-type impurity diffusion region 302 and through a third bridge portion 317 on the side of the N-type impurity diffusion region 302 opposite to the P-type impurity diffusion region 301. The dimension of a portion of the gate interconnect 312 provided between the P-type impurity diffusion region 301 and the N-type impurity diffusion region 302 is the same as the dimension of the gate electrodes 310 and 311, and the dimension of a portion of the gate interconnect 315 provided between the P-type impurity diffusion region 301 and the N-type impurity diffusion region 302 is the same as the dimension of the gate electrodes 313 and 314.

A plurality of source/drain contacts 318 are disposed on both sides of the gate electrodes 303, 308, 310 and 313 on the P-type impurity diffusion region 301, and a plurality of source/drain contacts 319 are disposed on both sides of the gate electrodes 304, 307, 311 and 314 on the N-type impurity diffusion region 302.

In the semiconductor device of this modification, one transistor includes four adjacent gate electrodes having the same gate length and the same gate width on each of the impurity diffusion regions 301 and 302. Accordingly, in the case where eight or a larger even number of gate electrodes are provided on the impurity diffusion regions 301 and 302, transistors are arranged in parallel.

As a characteristic of the design shape of the semiconductor device of this modification, as shown in FIG. 3A, a distance between the first bridge portion 309 and the P-type impurity diffusion region 301 and a distance between the second bridge portion 316 and the P-type impurity diffusion region 301 are both a distance DP3, namely, equal to each other, and a distance between the first bridge portion 309 and the N-type impurity diffusion region 302 and a distance between the third bridge portion 317 and the N-type impurity diffusion region 302 are both a distance DN3, namely, equal to each other.

FIG. 3B is a plan view of a shape of a pattern actually formed on the semiconductor substrate when the semiconductor device having the design shape of FIG. 3A is fabricated through the semiconductor device fabrication process including the photolithography process, the etching process and the resist removing process.

As shown in FIG. 3B, the gate electrodes 303, 306, 310 and 313 provided on the P-type impurity diffusion region 301 are respectively the same in the shape as the gate electrodes 304, 307, 311 and 314 provided on the N-type impurity diffusion region 302 although the arrangement direction is rotated by 180°.

Also in this modification, although not shown in the drawing, even when a GA/OD photomask alignment shift is caused, there arises no difference in the characteristic among transistors because the gate electrodes 303, 308, 310 and 313 made of the polysilicon film provided on the P-type impurity diffusion region 301 are the same in the shape as any of the gate electrodes 304, 307, 311 and 314 made of the polysilicon film provided on the N-type impurity diffusion region 302 when the arrangement direction is rotated by 180°. Furthermore, this effect can be attained also in transistors whose arrangement directions are different by 180° from those of the design shape of FIG. 3A.

In this manner, according to this modification, even when a GA/OD photomask alignment shift is caused, the variation in the electric characteristic among transistors can be prevented regardless of the transistor arrangement directions in the same manner as in Embodiment 1.

It is noted that the aforementioned effect can be attained not only in transistors whose arrangement directions are different by 180° from those of the design shape of FIG. 3A but also in transistors whose arrangement directions are different by 90° or 270° from those of the design shape of FIG. 3A.

Although the four gate interconnects are provided on the impurity diffusion region, namely, on a device forming region, in this modification, the number of gate interconnects is not particularly specified as far as it is four or a larger even number.

Modification 3 of Embodiment 1

Now, a semiconductor device according to Modification 3 of Embodiment 1 and a layout design method for the same will be described with reference to the accompanying drawings.

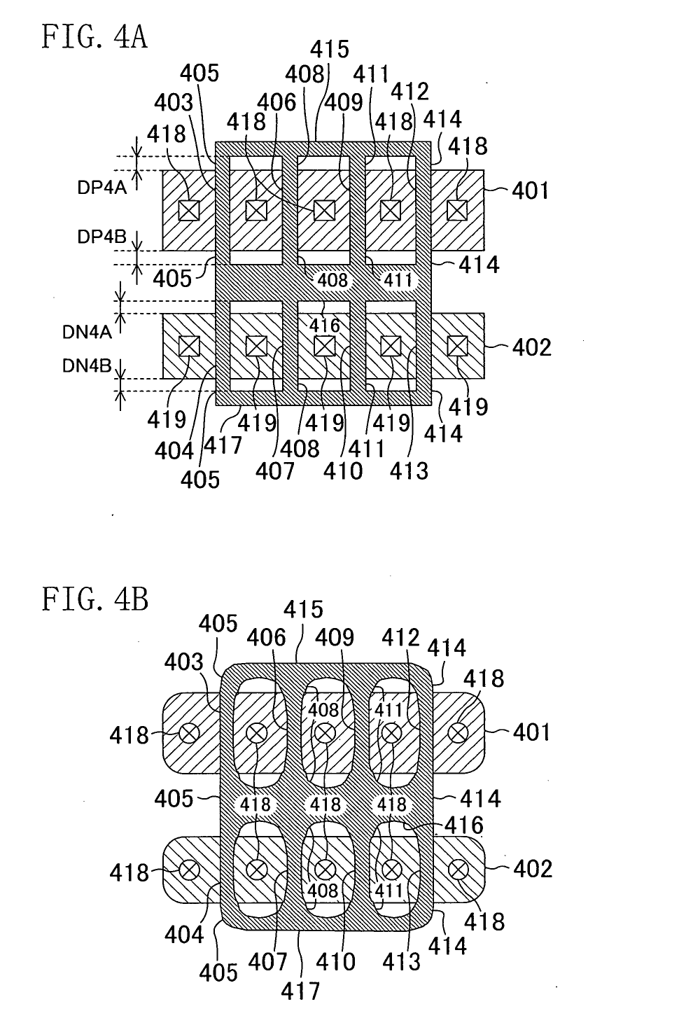

FIG. 4A is a plan view of a design shape of the semiconductor device of Modification 3 of Embodiment 1 and FIG. 4B is a plan view of a fabricated shape of the semiconductor device of Modification 3 of Embodiment 1.

As shown in FIG. 4A, a P-type impurity diffusion region 401 and an N-type impurity diffusion region 402 each surrounded with an isolation region (not shown) of STI or the like are formed on a semiconductor substrate (not shown) to be adjacent to each other.

A first conductive pattern (of, for example, a gate polysilicon film) corresponding to a gate electrode 403 and a gate electrode 404, a second conductive pattern (of, for example, a gate polysilicon film) corresponding to a gate electrode 406 and a gate electrode 407, a third conductive pattern (of, for example, a gate polysilicon film) corresponding to a gate electrode 409 and a gate electrode 410 and a fourth conductive pattern (of, for example, a gate polysilicon film) corresponding to a gate electrode 412 and a gate electrode 413 are formed on the P-type impurity diffusion region 401 and the N-type impurity diffusion region 402. Also, the first, second, third and fourth conductive patterns extend over the isolation region disposed on the both sides of the impurity diffusion regions 401 and 402 so as to form a gate interconnect 405, a gate interconnect 408, a gate interconnect 411 and a gate interconnect 414. In other words, the gate electrode 403 and the gate electrode 404 are electrically connected to each other through the gate interconnect 405, the gate electrode 406 and the gate electrode 407 are electrically connected to each other through the gate interconnect 408, the gate electrode 409 and the gate electrode 410 are electrically connected to each other through the gate interconnect 411, and the gate electrode 412 and the gate electrode 413 are electrically connected to each other through the gate interconnect 414.

Furthermore, the gate interconnects 405, 408, 411 and 414 are connected to one another through a first bridge portion 415 on the side of the P-type impurity diffusion region 401 opposite to the N-type impurity diffusion region 402, through a second bridge portion 416 between the P-type impurity diffusion region 401 and the N-type impurity diffusion region 402 and through a third bridge portion 417 on the side of the N-type impurity diffusion region 402 opposite to the P-type impurity diffusion region 401.

In the semiconductor device of this modification, one transistor includes four adjacent gate electrodes having the same gate length and the same gate width on each of the impurity diffusion regions 401 and 402. Accordingly, in the case where eight or a larger even number of gate electrodes are provided on each of the impurity diffusion regions 401 and 402, transistors are arranged in parallel.

As a characteristic of the design shape of the semiconductor device of this modification, as shown in FIG. 4A, a distance between the first bridge portion 415 and the P-type impurity diffusion region 401 and a distance between the second bridge portion 416 and the P-type impurity diffusion region 401 are both a distance DP4, namely, equal to each other, and a distance between the second bridge portion 416 and the N-type impurity diffusion region 402 and a distance between the third bridge portion 417 and the N-type impurity diffusion region 402 are both a distance DN4, namely, equal to each other.

FIG. 4B is a plan view of a shape of a pattern actually formed on the semiconductor substrate when the semiconductor device having the design shape of FIG. 4A is fabricated through the semiconductor device fabrication process including the photolithography process, the etching process and the resist removing process.

As shown in FIG. 4B, the gate electrodes 403, 406, 409 and 412 provided on the P-type impurity diffusion region 401 are respectively the same in the shape as the gate electrodes 404, 407, 410 and 413 provided on the N-type impurity diffusion region 402 although the arrangement direction is rotated by 180°.

Also in this modification, although not shown in the drawing, even when a GA/OD photomask alignment shift is caused, there arises no difference in the characteristic among transistors because the gate electrodes 403, 406, 409 and 412 provided on the P-type impurity diffusion region 401 are the same in the shape as any of the gate electrodes 404, 407, 410 and 413 provided on the N-type impurity diffusion region 402 when the arrangement direction is rotated by 180°. Furthermore, this effect can be attained also in transistors whose arrangement directions are different by 180° from those of the design shape of FIG. 4A.

In this manner, according to this modification, even when a GA/OD photomask alignment shift is caused, the variation in the electric characteristic among transistors can be prevented regardless of the transistor arrangement directions in the same manner as in Embodiment 1.

It is noted that the aforementioned effect can be attained not only in transistors whose arrangement directions are different by 180° from those of the design shape of FIG. 4A but also in transistors whose arrangement directions are different by 90° or 270° from those of the design shape of FIG. 4A.

Although the four gate interconnects are provided on the impurity diffusion region, namely, on the device forming region, in this modification, the number of gate interconnects is not particularly specified as far as it is plural.

### Embodiment b 2

Now, a semiconductor device according to Embodiment 2 and a layout design method for the same will be described with reference to the accompanying drawings.

In the structures of the semiconductor devices and the layout design methods described in Embodiment 1 and its modifications, no matter when the transistor arrangement direction is 0°, 90°, 180° or 270°, the variation in the electric characteristic among the transistors can be suppressed by making identical the shapes of the gate electrodes provided on the respective impurity diffusion regions.

In some cases, however, the variation in the electric characteristic among transistors cannot be suppressed depending upon a distance between a portion of a gate interconnect having a larger dimension along the gate length direction than a gate electrode and an impurity diffusion region.

Therefore, in Embodiment 2, a method for optimizing a distance between a portion of a gate interconnect having a larger dimension along the gate length direction than a gate electrode and an impurity diffusion region will be described.

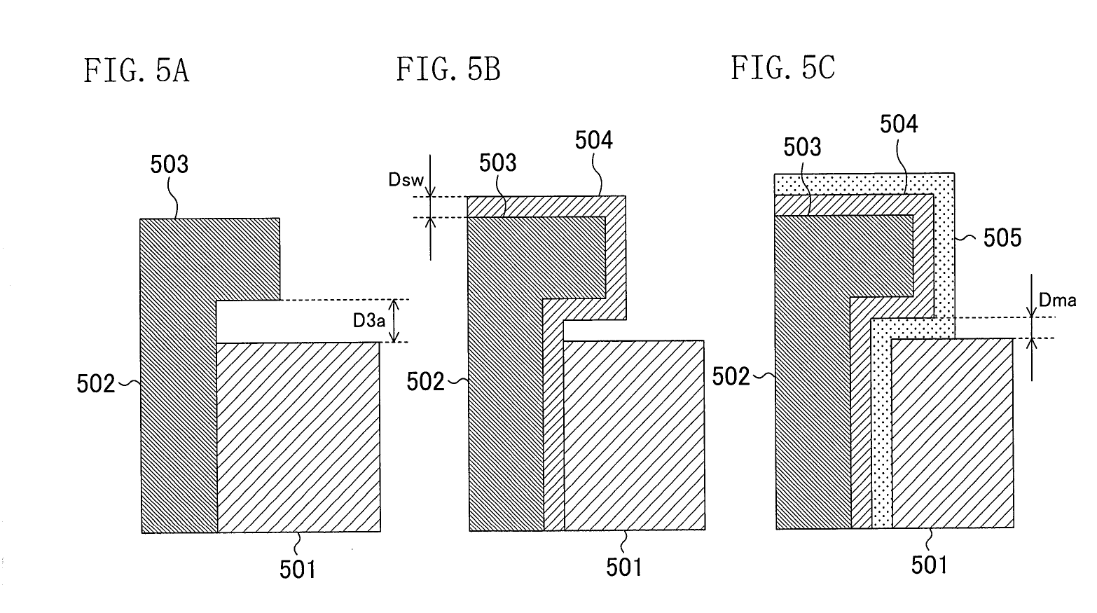

FIG. 5A is a plan view of a design shape (a shape of a gate polysilicon film) of a semiconductor device according to Embodiment 2, FIG. 5B is a plan view of a shape of an insulating sidewall formed on the side face of a gate electrode additionally shown in the plan view of FIG. 5A and FIG. 5C is a plan view of a GA/OD photomask alignment shift additionally shown in the plan view of FIG. 5B.

As shown in FIG. 5A, a gate electrode 502 is formed on an impurity diffusion region 501, and a gate interconnect 503 connected to the gate electrode 502 is formed on an isolation region (not shown) on one side of the impurity diffusion region 501. This semiconductor device is designed so that a distance between a portion of the gate interconnect 503 having a larger dimension along the gate length direction than the gate electrode 502 (such as the contact portion 105a and the dummy contact portions 105b and 105c of Embodiment 1, the contact portions 205a, 208a and 208b of Modification 1 of Embodiment 1, the first bridge portion 309, the second bridge portion 316 and the third bridge portion 317 of Modification 2 of Embodiment 1, or the first bridge portion 415, the second bridge portion 416 and the third bridge portion 417 of Modification 3 of Embodiment 1) and the impurity diffusion region 501 can be a distance D3a.

Next, as shown in FIG. 5B, when an insulating sidewall 504 with a thickness Dsw is formed on the side face of (around) the gate electrode 502 and the gate interconnect 503 after given semiconductor fabrication process, a distance between the portion, which has been provided with the insulating sidewall 504, of the gate interconnect 503 having the larger dimension along the gate length direction than the gate electrode 502 and the impurity diffusion region 501 becomes a distance D3a-Dsw.

Furthermore, the GA/OD photomask alignment shift is caused in the actual semiconductor fabrication process. In this case, assuming a region 505 with a width corresponding to the maximum value Dma of the GA/OD photomask alignment shift as shown in FIG. 5C, a distance (minimum distance) between the portion, which has been provided with the insulating sidewall 504, of the gate interconnect 503 having the larger dimension along the gate length direction than the gate electrode 503 and the impurity diffusion region 501 becomes a distance D3a-Dsw-Dma (which is 0 in FIG. 5C).

Therefore, in this embodiment, at the stage of design of the transistor, the distance between the portion of the gate interconnect 503 having the larger dimension along the gate length direction than the gate electrode 502 and the impurity diffusion region 501 is set to be not smaller than a sum of the thickness Dsw of the insulating sidewall 504 and the maximum value Dma of the GA/OD photomask alignment shift.

Thus, the portion of the gate interconnect 503 having the larger dimension along the gate length direction than the gate electrode 502 can be prevented from overlapping the impurity diffusion region 501. Accordingly, variation in the gate length and the gate width (which is determined depending upon the width of the impurity diffusion region 501) of the transistor can be prevented, and hence, the variation in the electric characteristic among the transistors can be avoided. Also, this effect can be attained no matter when the transistor arrangement direction is 0°, 90°, 180° or 270°.

Furthermore, since the distance between the portion of the gate interconnect 503 having the larger dimension along the gate length direction than the gate electrode 502 and the impurity diffusion region 501 is set to be not smaller than a sum of the thickness Dsw of the insulating sidewall 504 and the maximum value Dma of the GA/OD photomask alignment shift in this embodiment, not only the variation in the electric characteristic among transistors disposed in a single exposure region can be prevented but also the electric characteristics of transistors disposed in all the exposure regions on the whole wafer can be made uniform.

Modification of 1 of Embodiment 2

Now, a semiconductor device according to Modification 1 of Embodiment 2 and a layout design method for the same will be described with reference to the accompanying drawings.

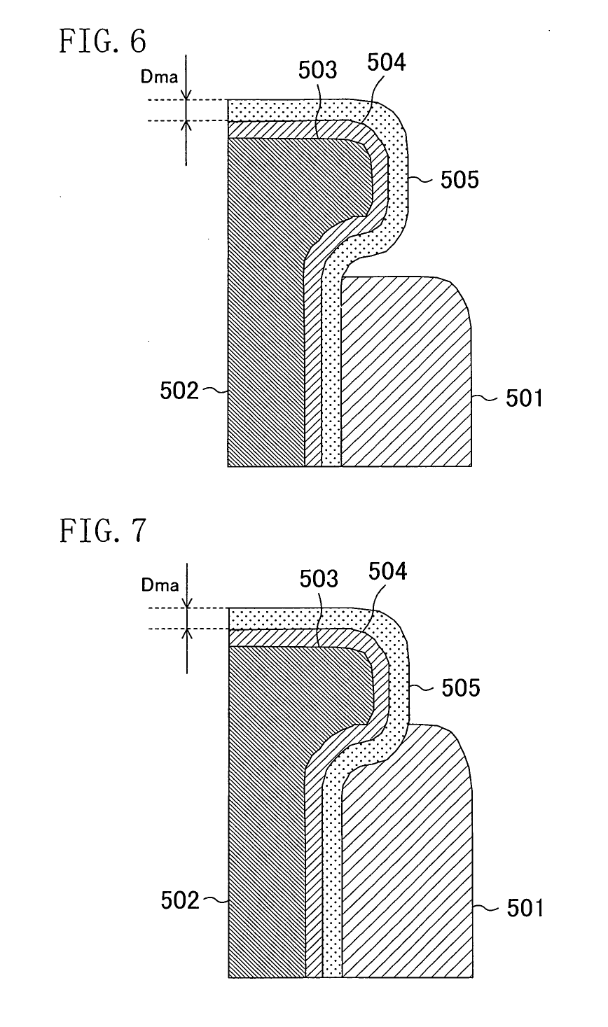

FIG. 6 is a plan view of a shape of a pattern actually formed on a semiconductor substrate when the semiconductor device having the design shape of FIG. 5A is fabricated through given semiconductor device fabrication process. In FIG. 6, like reference numerals are used to refer to like elements used in the semiconductor device shown in FIG. 5A so as to omit the description.

The fabricated shape of the semiconductor device shown in FIG. 6 is obtained in consideration of gate flaring occurring in the semiconductor fabrication process.

Specifically, in this modification, at the stage of transistor design, in consideration of the occurrence of the gate flaring, the distance between the portion of the gate interconnect 503 having the larger dimension along the gate length direction than the gate electrode 502 and the impurity diffusion region 501 is set to be not smaller than a sum of the thickness Dsw of the insulating sidewall 504, the maximum value Dma of the GA/OD photomask alignment shift and a maximum distance influenced by the gate flaring in forming the gate electrode 502 as shown in FIG. 6.

Thus, the portion of the gate interconnect 503 having the larger dimension along the gate length direction than the gate electrode 502 can be prevented from overlapping the impurity diffusion region 501. Accordingly, variation in the gate length and the gate width (which is determined depending upon the width of the impurity diffusion region 501) of the transistor can be prevented, and hence, the variation in the electric characteristic among transistors can be avoided. Also, this effect can be attained even when the gate flaring not considered in Embodiment 2 occurs or no matter when the transistor arrangement direction is 0°, 90°, 180° or 270°.

Modification 2 of Embodiment 2

Now, a semiconductor device according to Modification b 2 of Embodiment 2 and a layout design method for the same will be described with reference to the accompanying drawing.

FIG. 7 is a plan view of a shape of a pattern actually formed on a semiconductor substrate when the semiconductor device having the design shape of FIG. 5A is fabricated through given semiconductor device fabrication process. In FIG. 7, like reference numerals are used to refer to like elements used in the semiconductor device shown in FIG. 5A so as to omit the description.

Specifically, in this modification, at the stage of transistor design, the distance between the portion of the gate interconnect 503 having the larger dimension along the gate length direction than the gate electrode 502 and the impurity diffusion region 501 is set to be not larger than a value obtained by subtracting the maximum value Dma of the GA/OD photomask alignment shift from the thickness Dsw of the insulating sidewall 504. It is noted that when this value is negative, the portion of the gate interconnect 503 having the larger dimension along the gate length direction than the gate electrode 502 overlaps the impurity diffusion region 501 by a distance corresponding to the value.

Thus, the portion of the gate interconnect 503 having the larger dimension along the gate length direction than the gate electrode 502 can be made always overlap the impurity diffusion region 501. Accordingly, the gate electrode 502 provided on the impurity diffusion region 501 has the same shape no matter when the transistor arrangement direction is 0°, 90°, 180° or 270° or even when the gate flaring occurs, and hence, the variation in the electric characteristic among transistors can be avoided.

In this modification, the gate width of a transistor is determined not depending upon the width of the impurity diffusion region 501 but depending upon the length of, for example, a polysilicon film corresponding to the gate electrode 502.

Modification 3 of Embodiment 2

Now, a semiconductor device according to Modification 3 of Embodiment 2 and a layout design method for the same will be described with reference to the accompanying drawing.

As a characteristic of this modification, a plurality of gate interconnects having the characteristic of Modification b 2 of Embodiment 2 (namely, gate interconnects each having a portion thereof with a larger dimension along the gate length direction than a gate electrode always overlapping an impurity diffusion region) are provided on impurity diffusion regions, and the portions of the plural gate interconnects with the larger dimension along the gate length direction than the gate electrode are mutually connected.

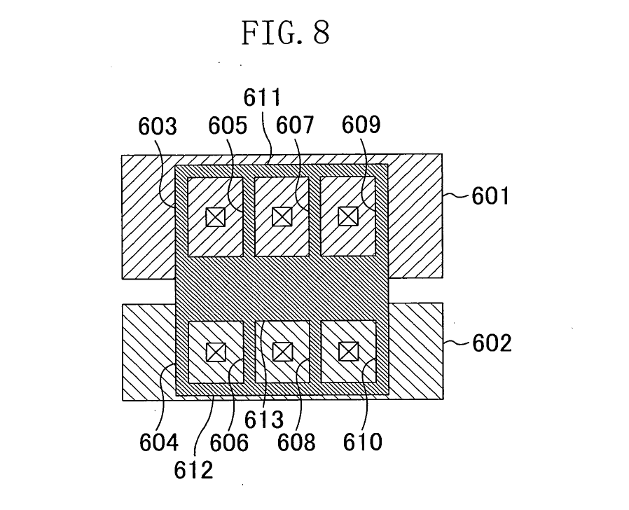

FIG. 8 is a plan view of a design shape of the semiconductor device of Modification 3 of Embodiment 2.

As shown in FIG. 8, a P-type impurity diffusion region 601 and an N-type impurity diffusion region 602 each surrounded with an isolation region (not shown) of STI or the like are formed on a semiconductor substrate (not shown) to be adjacent to each other.

A first conductive pattern (of, for example, a gate polysilicon film) corresponding to a gate electrode 603 and a gate electrode 604, a second conductive pattern (of, for example, a gate polysilicon film) corresponding to a gate electrode 605 and a gate electrode 606, a third conductive pattern (of, for example, a gate polysilicon film) corresponding to a gate electrode 607 and a gate electrode 608 and a fourth conductive pattern (of, for example, a gate polysilicon film) corresponding to a gate electrode 609 and a gate electrode 610 are formed on the P-type impurity diffusion region 601 and the N-type impurity diffusion region 602.

In this modification, the gate electrodes 603, 605, 607 and 609 are connected to one another through a first bridge portion 611 corresponding to a gate interconnect at one edge of the P-type impurity diffusion region 601 away from the N-type impurity diffusion region 602. Also, the gate electrodes 604, 606, 608 and 610 are connected to one another through a second bridge portion 612 corresponding to a gate interconnect at one edge of the N-type impurity diffusion region 602 away from the P-type impurity diffusion region 601. Furthermore, the gate electrodes 603, 605, 607 and 609 and the gate electrodes 604, 606, 608 and 610 are connected to one another through a third bridge portion 613, which is provided to extend over the P-type impurity diffusion region 601 and the N-type impurity diffusion region 602 and corresponds to a gate interconnect, at the other edge of the P-type impurity diffusion region 601 adjacent to the N-type impurity diffusion region 602 and at the other edge of the N-type impurity diffusion region 602 adjacent to the P-type impurity diffusion region 601.

In this modification, the portions of the gate interconnects having a larger dimension along the gate length direction than the gate electrodes 603 through 610 (namely, the first through third bridge portions 611 through 613) always overlap the impurity diffusion regions 601 and 602. Accordingly, no matter when the transistor arrangement direction is 0°, 90°, 180° or 270° or even when gate flaring occurs, the electric characteristic of transistors are not varied because the gate electrodes 603 through 610 are in an identical shape.

Also in this modification, the effective gate width of the transistor is determined depending upon the length of, for example, a polysilicon film corresponding to the gate electrodes 603 through 610.

Furthermore, in this modification, the first bridge portion 611 and the second bridge portion 612 are provided respectively within the P-type impurity diffusion region 601 and the N-type impurity diffusion region 602, and therefore, the polysilicon film or the like corresponding to the gate electrodes 603 through 610 never protrudes from the impurity diffusion regions 601 and 602, and thus, the layout area can be reduced. However, the first bridge portion 611 and the second bridge portion 612 may be provided so as to extend respectively outside the P-type impurity diffusion region 601 and the N-type impurity diffusion region 602.

### Embodiment 3

Now, a semiconductor device according to Embodiment 3 and a layout design method for the same will be described with reference to the accompanying drawings.

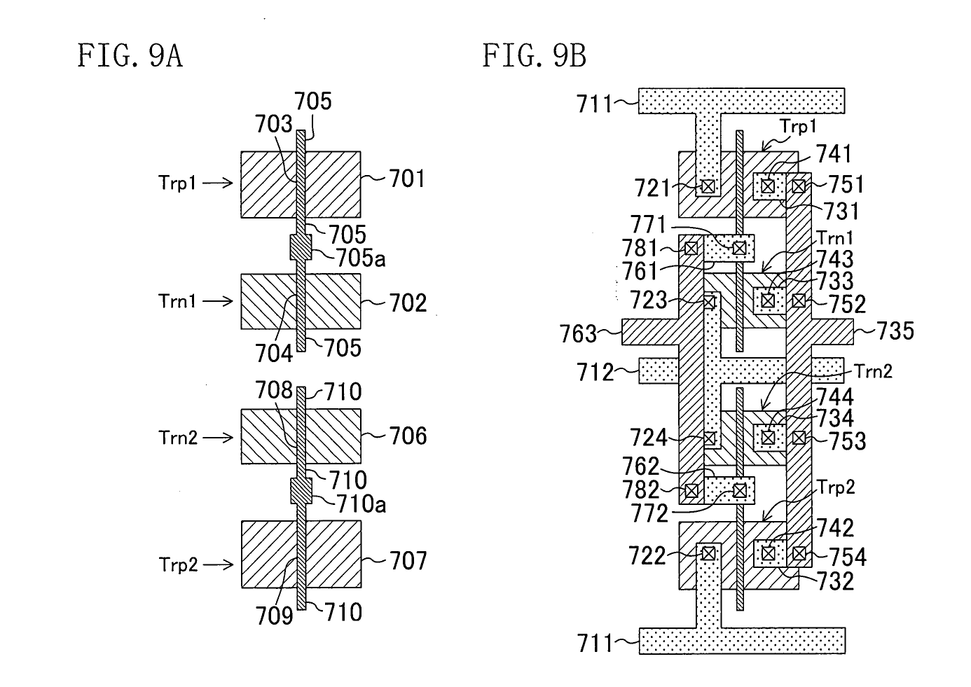

FIG. 9A is a plan view of design shapes of a first CMOS (complementary metal-oxide semiconductor) transistor pair and a second CMOS transistor pair included in the semiconductor device of Embodiment 3.

In the first CMOS transistor pair shown in FIG. 9A, a first P-type impurity diffusion region 701 where a first P-type transistor Trp1 is formed and a first N-type impurity diffusion region 702 where a first N-type transistor Trn1 is formed are formed to be adjacent to each other. In other words, the first CMOS transistor pair of FIG. 9A is composed of the first P-type transistor Trp1 and the first N-type transistor Trn1. In this embodiment, each of the impurity diffusion regions 701 and 702 is surrounded with an isolation region (not shown) of STI or the like. A conductive pattern (of, for example, a gate polysilicon film) corresponding to a gate electrode 703 and a gate electrode 704 is formed on the first P-type impurity diffusion region 701 and the first N-type impurity diffusion region 702, and the conductive pattern extends over the isolation region on both sides of the impurity diffusion regions 701 and 702 so as to form a gate interconnect 705. In other words, the gate electrode 703 and the gate electrode 704 are electrically connected to each other through the gate interconnect 705. Also, the gate interconnect 705 has, between the first P-type impurity diffusion region 701 and the first N-type impurity diffusion region 702, a contact portion 705a having a larger dimension along the gate length direction than the gate electrodes 703 and 704.

In the second CMOS transistor pair shown in FIG. 9A, a second N-type impurity diffusion region 706 where a second N-type transistor Trn2 is formed and a second P-type impurity diffusion region 707 where a second P-type transistor Trp2 is formed are formed to be adjacent to each other. In other words, the second CMOS transistor pair of FIG. 9A is composed of the second N-type transistor Trn2 and the second P-type transistor Trp2. In this embodiment, each of the impurity diffusion regions 706 and 707 is surrounded with an isolation region (not shown) of STI or the like. A conductive pattern (of, for example, a gate polysilicon film) corresponding to a gate electrode 708 and a gate electrode 709 is formed on the second N-type impurity diffusion region 706 and the second P-type impurity diffusion region 707, and the conductive pattern extends over the isolation region on both sides of the impurity diffusion regions 706 and 707 so as to form a gate interconnect 710. In other words, the gate electrode 708 and the gate electrode 709 are electrically connected to each other through the gate interconnect 710. Also, the gate interconnect 710 has, between the second N-type impurity diffusion region 706 and the second P-type impurity diffusion region 707, a contact portion 710a having a larger dimension along the gate length direction than the gate electrodes 708 and 709.

It is noted that the first CMOS transistor pair and the second CMOS transistor pair of FIG. 9A are different from each other in the arrangement direction by 180°.

FIG. 9B is a plan view of an example of a design shape (an interconnect connection relationship) of one logic circuit constructed by connecting the first CMOS transistor pair and the second CMOS transistor pair of FIG. 9A in parallel. In FIG. 9B, the reference numerals of the first CMOS transistor pair and the second CMOS transistor pair shown in FIG. 9A are partly omitted.

As shown in FIG. 9B, the first P-type transistor Trp1 and the second P-type transistor Trp2 are connected to a Vdd interconnect 711 respectively through source contacts 721 and 722. Also, the first N-type transistor Trn1 and the second N-type transistor Trn2 are connected to a Vss interconnect 712 respectively through source contacts 723 and 724. Furthermore, the first P-type transistor Trp1 is connected to a second-layer metal interconnect 735 through a drain contact 741, a first-layer metal interconnect 731 and a via 751; the second P-type transistor Trp2 is connected to the second-layer metal interconnect 735 through a drain contact 742, a first-layer metal interconnect 732 and a via 752; the first N-type transistor Trn1 is connected to the second-layer metal interconnect 735 through a drain contact 743, a first-layer metal interconnect 733 and a via 753; and the second N-type transistor Trn2 is connected to the second-layer metal interconnect 735 through a drain contact 744, a first-layer metal interconnect 734 and a via 754. The first P-type transistor Trp1 and the first N-type transistor Trn1 are connected to a second-layer metal interconnect 763 through a gate contact 771 (which is provided on the contact portion 705a of the first CMOS transistor pair shown in FIG. 9A), a first-layer metal interconnect 761 and a via 781, and the second P-type transistor Trp2 and the second N-type transistor Trn2 are connected to the second-layer metal interconnect 763 through a gate contact 772 (which is provided on the contact portion 710a of the second CMOS transistor pair shown in FIG. 9A), a first-layer metal interconnect 762 and a via 782.

Since the arrangement directions of the first CMOS transistor pair and the second CMOS transistor pair included in the logic circuit of FIG. 9B are different from each other by 180°, the layout of the logic circuit shown in FIG. 9B is the same as the layout of a logic circuit in which the transistor arrangement direction is different from that of FIG. 9B by 180°. In other words, the two kinds of CMOS transistor pairs different in the arrangement direction by 180° are provided in one logic circuit. Therefore, even when, for example, a GA/OD photomask alignment shift is caused, a shift of the electric characteristic of the first CMOS transistor pair and a shift of the electric characteristic of the second CMOS transistor pair cancel each other.

In this manner, in the semiconductor device according to this embodiment, even when a GA/OD photomask alignment shift occurs or gate flaring occurs, relative variation in the electric characteristic among the transistors disposed in a single exposure region (for example, one chip region) can be avoided.

### Comparative Example of Embodiment 3

Now, a semiconductor device according to a comparative example of Embodiment 3 and a layout design method for the same will be described with reference to the accompanying drawings.

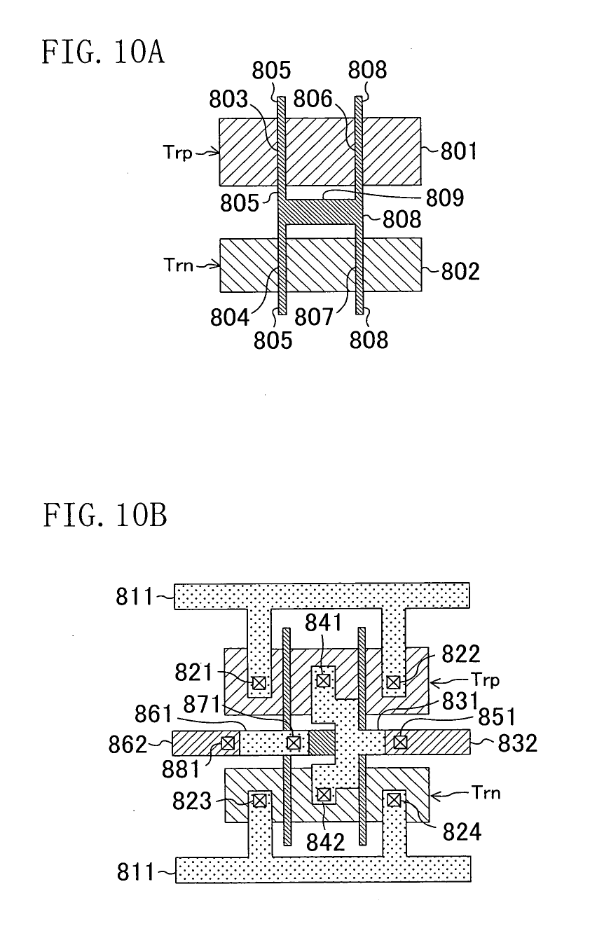

FIG. 10A is a plan view of a design shape of a CMOS transistor pair included in the semiconductor device of the comparative example.

In the CMOS transistor pair of FIG. 10A, a P-type impurity diffusion region 801 where a P-type transistor Trp is formed and an N-type impurity diffusion region 802 where an N-type transistor Trn is formed are formed to be adjacent to each other. In other words, the CMOS transistor pair of FIG. 10A is composed of the P-type transistor Trp and the N-type transistor Trn. Each of the impurity diffusion regions 801 and 802 is surrounded with an isolation region (not shown) of STI or the like.

A first conductive pattern (of, for example, a gate polysilicon film) corresponding to a gate electrode 803 and a gate electrode 804 and a second conductive pattern (of, for example, a gate polysilicon film) corresponding to a gate electrode 806 and a gate electrode 807 are formed to be adjacent to each other on the P-type impurity diffusion region 801 and the N-type impurity diffusion region 802. Also, the first conductive pattern and the second conductive pattern extend over the isolation region on both the sides of the impurity diffusion regions 801 and 802 so as to form a gate interconnect 805 and a gate interconnect 808. In other words, the gate electrode 803 and the gate electrode 804 are electrically connected to each other through the gate interconnect 805, and the gate electrode 806 and the gate electrode 807 are electrically connected to each other through the gate interconnect 808. Also, the gate interconnect 805 and the gate interconnect 808 adjacent to each other are connected to each other through a bridge portion 809 between the P-type impurity diffusion region 801 and the N-type impurity diffusion region 802.

FIG. 10B is a plan view of an example of a design shape (an interconnect connection relationship) of one logic circuit including the CMOS transistor pair of FIG. 10A. In FIG. 10B, the reference numerals of the CMOS transistor pair shown in FIG. 10A are partly omitted.

As shown in FIG. 10B, the P-type transistor Trp is connected to a first-layer metal interconnect 811 through source contacts 821 and 822, and the N-type transistor Trn is connected to the first-layer metal interconnect 811 through source contacts 823 and 824. Also, the P-type transistor Trp is connected to a second-layer metal interconnect 832 through a drain contact 841, a first-layer metal interconnect 831 and a via 851, and the N-type transistor Trn is connected to the second-layer metal interconnect 832 through a drain contact 842, the first-layer metal interconnect 831 and the via 851. Furthermore, the P-type transistor Trp and the N-type transistor Trn are connected to a second-layer metal interconnect 862 through a gate contact 871 (which is provided on the bridge portion 809 of FIG. 10A), a first-layer metal interconnect 861 and a via 881.

In this case, it goes without saying that the layout of the logic circuit of FIG. 10B is different from the layout of a logic circuit in which the arrangement direction is different from that of the logic circuit of FIG. 10B by 180°.

Specifically, in this comparative example, when, for example, a GA/OD photomask alignment shift occurs or gate flaring occurs, relative variation in the electric characteristic among the transistors is caused in a single exposure region (for example, one chip region).

### Embodiment 4

Now, a semiconductor device according to Embodiment 4 and a layout design method for the same will be described with reference to the accompanying drawing.

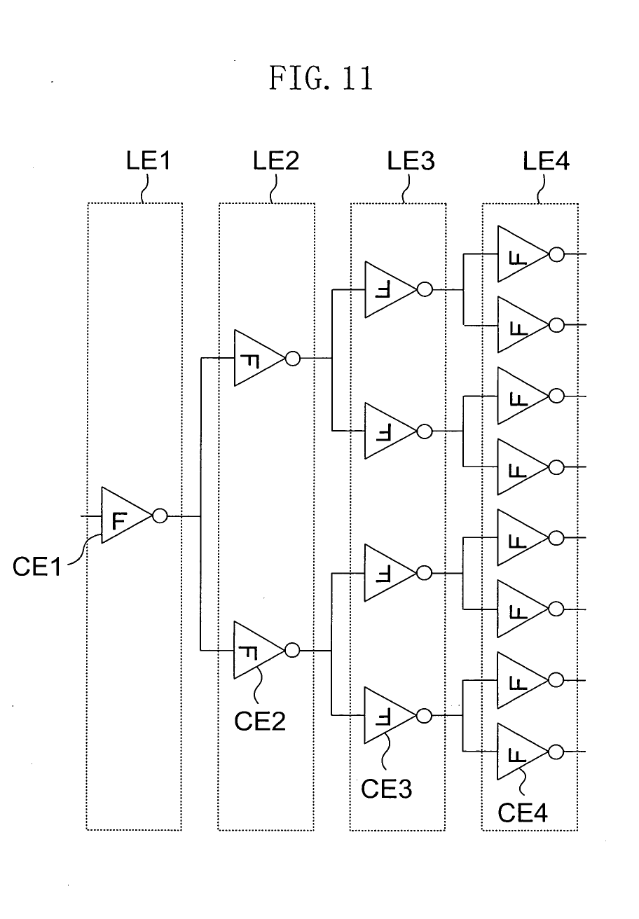

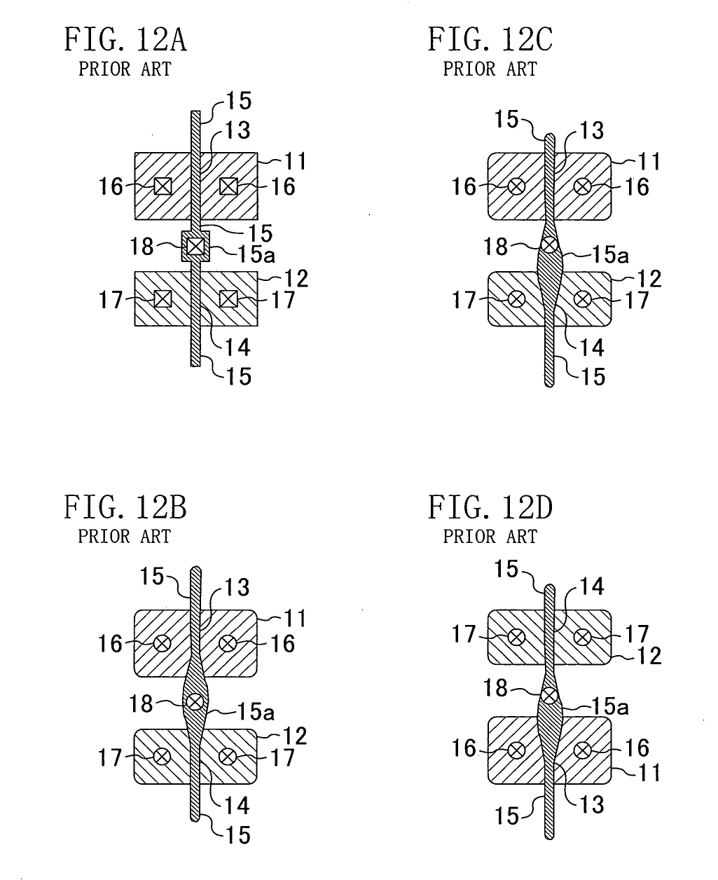

FIG. 11 is a schematic diagram of a semiconductor device of Embodiment 4, and specifically a clock tree of an LSI.

As shown in FIG. 11, the clock tree of this embodiment has four hierarchies LE1, LE2, LE3 and LE4. The hierarchies LE1, LE2, LE3 and LE4 respectively include transistor cell groups CE1, CE2, CE3 and CE4 for propagating a clock. It is noted that the arrangement direction of each transistor cell is shown correspondingly to the direction of a letter “F” in FIG. 11.

As a characteristic of the clock tree of this embodiment, the arrangement directions of the transistor cells are unified in each hierarchy of the clock tree. Specifically, assuming that the arrangement direction of the transistor cell group CE1 of the hierarchy LE1 is unified to, for example, 0°, the arrangement direction of the transistor cell group CE2 of the hierarchy LE2 is unified to, for example, 90°, the arrangement direction of the transistor cell group CE3 of the hierarchy LE3 is unified to, for example, 180° and the arrangement direction of the transistor cell group CE4 of the hierarchy LE4 is unified to, for example, 270°.

In this manner, since the arrangement directions of transistors used for propagating a clock are unified in each hierarchy of the clock tree in this embodiment, the clock propagation speeds of the transistors can be made relatively equal in each hierarchy, namely, a difference in the basic ability among the transistors can be relatively unified in each hierarchy, and therefore, clock skew can be suppressed. Accordingly, a margin can be designed to be small owing to the suppression of the clock skew, and hence, the area of the LSI chip can be reduced. As a result, the LSI can attain higher performance than a conventional one in the same chip area.

What is claimed is:

1. A layout design method for a semiconductor device, which includes a device forming region formed on a substrate; an isolation region formed on said semiconductor substrate so as to surround said device forming region; a gate electrode formed on said device forming region; and a gate interconnect connected to said gate electrode and formed on both sides of said device forming region on said isolation region, comprising the step of:
designing said semiconductor device in such a manner that said gate interconnect has a first portion with a larger dimension along a gate length direction than said gate electrode on one side of said device forming region and a second portion with a larger dimension along the gate length direction than said gate electrode on the other side of said device forming region, with a distance between said first portion and said device forming region and a distance between said second portion and said device forming region set equal to each other.

2. The layout design method for a semiconductor device of claim 1,
wherein said first portion and said second portion are designed to be in an identical shape.

3. The layout design method for a semiconductor device of claim 1,
wherein said first portion and said second portion are designed to have an identical length in portions thereof opposing said device forming region.

4. A layout design method for a semiconductor device, which includes a device forming region formed on a semiconductor substrate; an isolation region formed on said semiconductor substrate so as to surround said device forming region; an even number not less than two of gate electrodes formed on said device forming region; and an even number not less than two of gate interconnects respectively connected to said even number of gate electrodes and formed on both sides of said device forming region on said isolation region, comprising the steps of:
designing said semiconductor device in such a manner that a first half of said even number of gate interconnects each have a first portion with a larger dimension along a gate length direction than said gate electrodes connected thereto on a first side of said device forming region and each have a dimension along the gate length direction equal to a dimension of said gate electrodes connected thereto on a second side of said device forming region;
designing said semiconductor device in such a manner that a second half of said even number of gate interconnects each have a second portion with a larger dimension along the gate length direction than said gate electrodes connected thereto on said second side of said device forming region and each have a dimension along the gate length direction equal to the dimension of said gate electrodes connected thereto on said first side of said device forming region; and
setting a distance between said first portion of each of said first half of gate interconnects and said device forming region to be equal to a distance between said second portion of each of said second half of gate interconnects and said device forming region.

5. The layout design method for a semiconductor device of claim 1,
wherein each distance from said first portion and said second portion to said device forming region is set to be not smaller than a sum of a thickness of an insulating sidewall formed on a side face of said gate electrode and a maximum value of an alignment shift between a photomask used for forming said gate electrode and a photomask used for forming said device forming region.

6. The layout design method for a semiconductor device of claim 1,
wherein each distance from said first portion and said second portion to said device forming region is set to be not smaller than a sum of a thickness of an insulating sidewall formed on a side face of said gate electrode, a maximum value of an alignment shift between a photomask used for forming said gate electrode and a photomask used for forming said device forming region and a maximum distance influenced by gate flaring in forming said gate electrode.

7. The layout design method for a semiconductor device of claim 1,
wherein each distance from said first portion and said second portion to said device forming region is set to be not larger than a value obtained by subtracting, from a thickness of an insulating sidewall formed on a side face of said gate electrode, a maximum value of an alignment shift between a photomask used for forming said gate electrode and a photomask used for forming said device forming region.

8. A layout design method for a semiconductor device, which includes a device forming region formed on a semiconductor substrate; an isolation region formed on said semiconductor substrate so as to surround said device forming region; an even number not less than four of gate electrodes formed on said device forming region; and an even number not less than four of gate interconnects respectively connected to said even number of gate electrodes and formed on both sides of said device forming region on said isolation region, comprising the steps of:
designing said semiconductor device in such a manner that a first pair of adjacent gate interconnects out of said even number of gate interconnects are connected to each other through a first bridge portion on a first side of said device forming region and each have a dimension along a gate length direction equal to a dimension of gate electrodes connected to said first pair of gate interconnects on a second side of said device forming region;
designing said semiconductor device in such a manner that a second pair of adjacent gate interconnects out of said even number of gate interconnects are connected to each other through a second bridge portion on said second side of said device forming region and each have a dimension along the gate length direction equal to a dimension of gate electrodes connected to said second pair of gate interconnects on said first side of said device forming region; and
setting a distance between said first bridge portion and said device forming region to be equal to a distance between said second bridge portion and said device forming region.

9. A layout design method for a semiconductor device, which includes a device forming region formed on a semiconductor substrate; an isolation region formed on said semiconductor substrate so as to surround said device forming region; a plurality of gate electrodes formed on said device forming region; and a plurality of gate interconnects respectively connected to said plurality of gate electrodes and formed on both sides of said device forming region on said isolation region, comprising the steps of:
designing said semiconductor device in such a manner that said plurality of gate interconnects are connected to one another through a first bridge portion on a first side of said device forming region and through a second bridge portion on a second side of said device forming region; and
setting a distance between said first bridge portion and said device forming region to be equal to a distance between said second bridge portion and said device forming region.

10. The layout design method for a semiconductor device of claim 8,
wherein each distance from said first bridge portion and said second bridge portion to said device forming region is set to be not smaller than a sum of a thickness of an insulating sidewall formed on a side face of each of said gate electrodes and a maximum value of an alignment shift between a photomask used for forming said gate electrodes and a photomask used for forming said device forming region.

11. The layout design method for a semiconductor device of claim 8,
wherein each distance from said first bridge portion and said second bridge portion to said device forming region is set to be not smaller than a sum of a thickness of an insulating sidewall formed on a side face of each of said gate electrodes, a maximum value of an alignment shift between a photomask used for forming said gate electrodes and a photomask used for forming said device forming region and a maximum distance influenced by gate flaring in forming said gate electrodes.

12. The layout design method for a semiconductor device of claim 8,
wherein each distance from said first bridge portion and said second bridge portion to said device forming region is set to be not larger than a value obtained by subtracting, from a thickness of an insulating sidewall formed on a side face of each of said gate electrodes, a maximum value of an alignment shift between a photomask used for forming said gate electrodes and a photomask used for forming said device forming region.

13. A semiconductor device comprising:
a device forming region formed on a semiconductor substrate;
an isolation region formed on said semiconductor substrate so as to surround said device forming region;
a gate electrode formed on said device forming region; and
a gate interconnect connected to said gate electrode and formed on both sides of said device forming region on said isolation region,
wherein said gate interconnect has a first portion with a larger dimension along a gate length direction than said gate electrode on a first side of said device forming region and has a second portion with a larger dimension along the gate length direction than said gate electrode on a second side of said device forming region, and
said first portion and said second portion are symmetrical with respect to said device forming region.

14. A semiconductor device comprising:
one logic circuit in which a first CMOS transistor pair including a first NMOS region and a first PMOS region is connected in parallel to a second CMOS transistor pair that includes a second NMOS region and a second PMOS region and is different from said first CMOS transistor pair in an arrangement direction by 180°.

15. A semiconductor device comprising:
a clock tree in which arrangement directions of transistors are unified in each hierarchy of said clock tree.
